(19) United States
(12) Patent Application Publication
(10) Pub. No.: US 2007/0241827 A1
(43) Pub. Date: Oct. 18, 2007

(54) SURFACE MOUNT CRYSTAL OSCILLATOR

(76) Inventor: Hidenori HARIMA, Sayama-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/691,954

(22) Filed: Mar. 27, 2007

(30) Foreign Application Priority Data
Mar. 28, 2006 (JP) 2006-089233

(51) Int. Cl. H03B 5/32

(52) U.S. Cl. 331/158

(57) ABSTRACT

A crystal oscillator for surface-mounting on a circuit board comprises a package body which includes a bottom wall layer, and a frame wall layer having an opening and laminated on the bottom wall layer, where the opening defines a recess in the package body, a crystal blank contained in the recess, an IC chip contained in the recess, and mounting terminals disposed at four corners on an outer bottom surface of the package body for use in mounting the crystal oscillator. An oscillation circuit using the crystal blank is integrated in the IC chip. The package body is formed with a cavity in at least a central region of the outer bottom surface thereof, and no electrode layer is disposed in the cavity.

### BACKGROUND OF THE INVENTION

1. Field of the Invention

The present invention relates to a surface mount crystal oscillator, and more particularly, to a surface mount crystal oscillator which prevents a change in oscillation frequency when a sudden thermal change is applied thereto.

2. Description of the Related Art

A surface mount crystal oscillator has a quartz crystal blank and an IC chip that has integrated therein an oscillation circuit using the crystal blank, both of which are accommodated in a package of a surface mount type. Such crystal oscillators are built in a variety of portable electronic devices in particular as reference sources for frequency and time because of their small sizes and light weights. In recent years, the surface mount crystal oscillators have been increasingly reduced in size, and are now required to have, for example, outer planar dimensions of 2.5 mm×2.0 mm or smaller.

FIG. 1A is a cross-sectional view illustrating a conventional surface mount crystal oscillator, and FIG. 1B is a bottom view of the crystal oscillator. As shown in U.S. Pat. No. 6,720,837, for example, the illustrated surface mount crystal oscillator comprises IC chip 2 and crystal blank 3 contained in a recess defined in package body 1 of a surface mount type, and metal cover 4 placed over the recess to hermetically seal IC chip 2 and crystal blank 3 therein. Package body 1 is formed of laminated ceramics which comprise substantially rectangular flat bottom wall layer 1a, and frame wall layer 1b laminated on bottom wall layer 1a and having a substantially rectangular opening. Bottom wall layer 1a has main surfaces which are both made flat. The opening formed through frame wall layer 1b defines the recess in one main surface of package body 1 for accommodating IC chip 2 and crystal blank 3. A step is formed on an inner wall surface on one side of frame wall layer 1b, and a pair of crystal holding terminals (not shown) are formed on the top surface of the step for use in holding crystal blank 3. Mounting terminals 5 are disposed at four corners on the other main surface of package body 1, i.e., the outer bottom surface of package body 1 for surface mounting the crystal oscillator on a circuit board. Mounting terminals 5 are made of an electrode layer, i.e., a metal film disposed on the surface of bottom wall layer 1a made of ceramic. Mounting terminals 5 include a power supply terminal, a ground terminal, an output terminal for supplying an oscillation output, and the like.

IC chip 2 has electronic circuits integrated on a semiconductor substrate, where the electronic circuits includes an oscillation circuit which uses crystal blank 3. The oscillation circuit also includes a temperature compensation mechanism for compensating crystal blank 3 for frequency-temperature characteristics, and the temperature compensation mechanism also includes a temperature sensor for measuring the ambient temperature. Such an oscillation circuit is formed on one main surface of a semiconductor substrate by a general semiconductor device fabricating process. Accordingly, a circuit forming surface will herein refer to one of the two main surfaces of IC chip 2 on which the oscillation circuit is formed on the semiconductor substrate. A plurality of IC terminals are also formed on the circuit forming surface for connecting IC chip 2 to external circuits. The IC terminals include a power supply terminal, a ground terminal, an oscillation output terminal, a pair of connection terminals for connection with the crystal blank, and the like.

Circuit terminals are disposed on the bottom-surface of the recess in package body 1 in correspondence to the IC terminals. The circuit terminals corresponding to the power supply terminal, ground terminal, and oscillation output terminal on IC chip 2 are electrically connected to mounting terminals 5, respectively, through conductive paths formed on a lamination plane between frame wall layer 1b and bottom wall layer 1a, and outer surfaces of package body 1. Circuit terminals corresponding to a pair of connection terminals on IC chip 2 are electrically connected to the aforementioned pair of crystal holding terminals. IC chip 2 is secured to the bottom surface of the recess by electrically and mechanically connecting the IC terminals to the circuit terminals through ultrasonic thermo-compression bonding using bumps 6, such that the circuit forming surface opposes the bottom surface of the recess in package body 1. Further, write terminals, not shown, are disposed on an outer side surface of package body 1 for writing temperature compensation data which should be held in a memory circuit within the temperature compensation mechanism. Test terminals are also disposed on the outer side surface of package body 1 for independently measuring oscillation characteristics of crystal blank 3 as a crystal element. In this connection, Japanese Patent Laid-open Application No. Hei-10-190355 (JP-A-10-190355) discloses a surface mount crystal oscillator which comprises write terminals and test terminals disposed in a recess which is formed in an outer bottom surface of a package body.

As illustrated in FIG. 2, crystal blank 3 is, for example, a substantially rectangular AT-cut quartz crystal blank, and is provided with excitation electrodes 7a on both main surfaces, respectively. Lead-out electrodes 7b are extended from these excitation electrodes 9a, respectively, toward both ends of one side of crystal blank 3. Both ends of the one side of crystal blank 3, to which lead-out electrodes 7b are extended, are secured to the crystal holding terminals formed on the step in the recess with conductive adhesive 8, to electrically and mechanically connect crystal blank 3 to the crystal holding terminals, thereby holding crystal blank 3 within the recess (see FIG. 1A).

Metal cover 4 is bonded to a metal ring including a metal film disposed on an upper surface of frame wall layer 1b, that is, an open end surface around the recess of package body 1 by seam welding or beam welding, and is electrically connected to the ground terminal within mounting terminals 5 through a via hole formed through frame wall layer 1b.

The crystal oscillator thus configured is carried, for example, on a circuit board of a portable device into a high-temperature furnace for heating, so that the crystal oscillator is surface-mounted on the circuit board by soldering or the like.

However, in the surface mount crystal oscillator in the configuration described above, IC chip 2 is placed at a position closer to the circuit board than crystal blank 3 within package body 1, thus making IC chip 2 more susceptible to the influence of a sudden thermal change on the circuit board. A sudden temperature change on the circuit board causes a temperature difference between IC chip 2 and crystal blank 3, with the result that a temperature detected by the temperature sensor within IC chip 2 differs from the operating temperature of crystal blank 3. Eventually, a compensation action by the temperature compensation mechanism is much removed from the actual temperature of crystal blank 3, to exacerbate the frequency stability to the temperature in the crystal oscillator.

Particularly, when the foregoing crystal oscillator is used as a reference for communication frequency in mobile phones or the like, such exacerbated frequency stability would give rise to grave problems. Even when the crystal oscillator does not comprise the temperature compensation mechanism, a sudden thermal change on the circuit board causes a sudden change in oscillation frequency, giving rise to a variety of problems in the operation of a device which employs the crystal oscillator.

### SUMMARY OF THE INVENTION

It is an object of the present invention to provide a crystal oscillator surface-mounted on a circuit board, which is configured to alleviate a sudden change in oscillation frequency caused by a thermal change on the circuit board.

The above object is achieved by a surface mount crystal oscillator which includes a package body having a bottom wall layer and a frame wall layer having an opening and laminated on the bottom wall layer, where the opening defines a recess in the package body, a crystal blank contained in the recess, an IC chip contained in the recess, and having an oscillation circuit, using the crystal blank, integrated therein, and mounting terminals disposed at four corners on an outer bottom surface of the package body for use in mounting the crystal oscillator, wherein the package body is formed with a cavity in at least a central region of the outer bottom surface, and no electrode layer is disposed in the cavity.

Given the configuration as described above, since the cavity is formed in the outer bottom surface of the package body without any electrode layer, an air layer having a small thermal conductivity is defined between the circuit board and crystal oscillator. As a result, the crystal oscillator can alleviate the influence of a thermal change on the circuit board to reduce a difference in temperature between the IC chip and crystal blank, and prevent a sudden change in oscillation frequency, as compared with a case in which a package body has a flat outer bottom surface and the entirety of the flat outer bottom surface is in contact with or in close proximity to a circuit board.

The crystal oscillator of the present invention differs from the one disclosed in JP-A-10-190355 in that no electrode layer or metal film is formed on an exposed surface in the cavity on the outer bottom surface of the package body. As a result, since heat is not absorbed by or conducted to an electrode layer such as test terminals, the crystal oscillator is even less affected by thermal changes on the circuit board. For reference, from the fact that gold (Au) generally used for electrode layers has a thermal conductivity of 317 W/mK, whereas ceramic which constitutes the package body has a thermal conductivity of 17 W/mK, the influence exerted by the presence or absence of the electrode layer cannot be neglected because the two materials largely differ from each other in the thermal conductivities.

In the present invention, the cavity may be open to at least one side of the outer bottom surface of the package body to communicate with an outer side surface of the package body. According to this configuration, since the cavity is not isolated from outside air, heat within the cavity can escape with greater ease to further reduce a difference in temperature between the crystal blank and IC chip. Particularly, when the cavity is extended through two or more sides of the outer bottom surface of the package body, larger heat radiation effects can be accomplished than the cavity extended only through one side.

### BRIEF DESCRIPTION OF THE DRAWINGS

FIGS. 1A and 1B are a cross-sectional view and a bottom view, respectively, illustrating the configuration of a conventional surface mount crystal oscillator;

FIG. 2 is a plan view of a crystal blank;

FIGS. 3A and 3B are a cross-sectional view and a bottom view, respectively, illustrating the configuration of a surface mount crystal oscillator according to one embodiment of the present invention; and

FIG. 4 is a bottom view illustrating the configuration of a surface mount crystal oscillator according to another embodiment of the present invention.

### DETAILED DESCRIPTION OF THE PREFERRED EMBODIMENTS

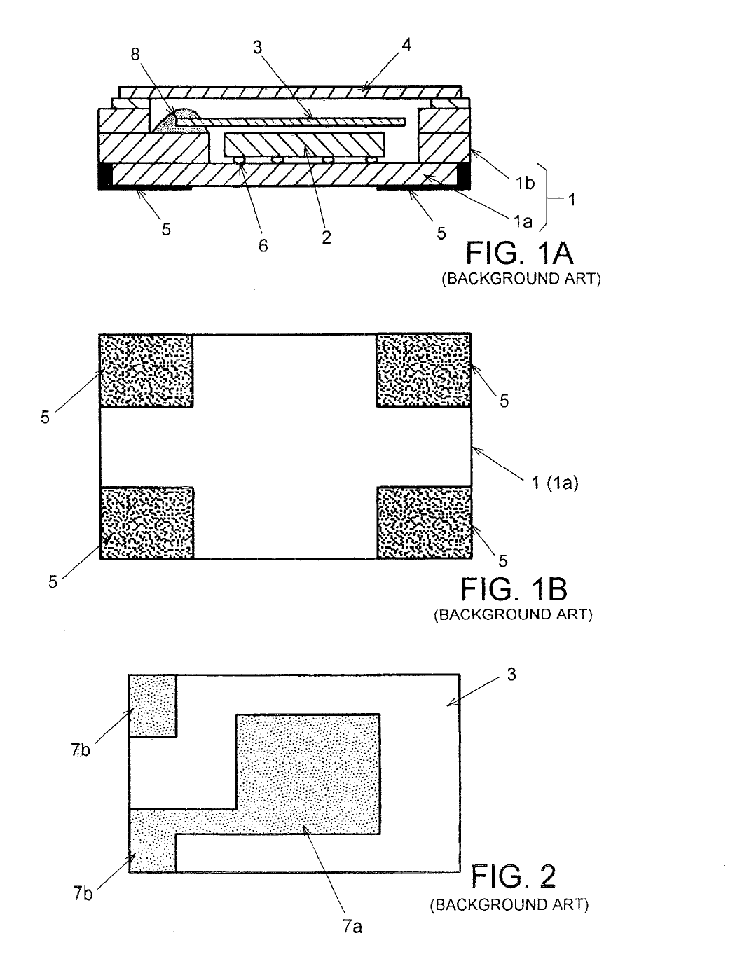

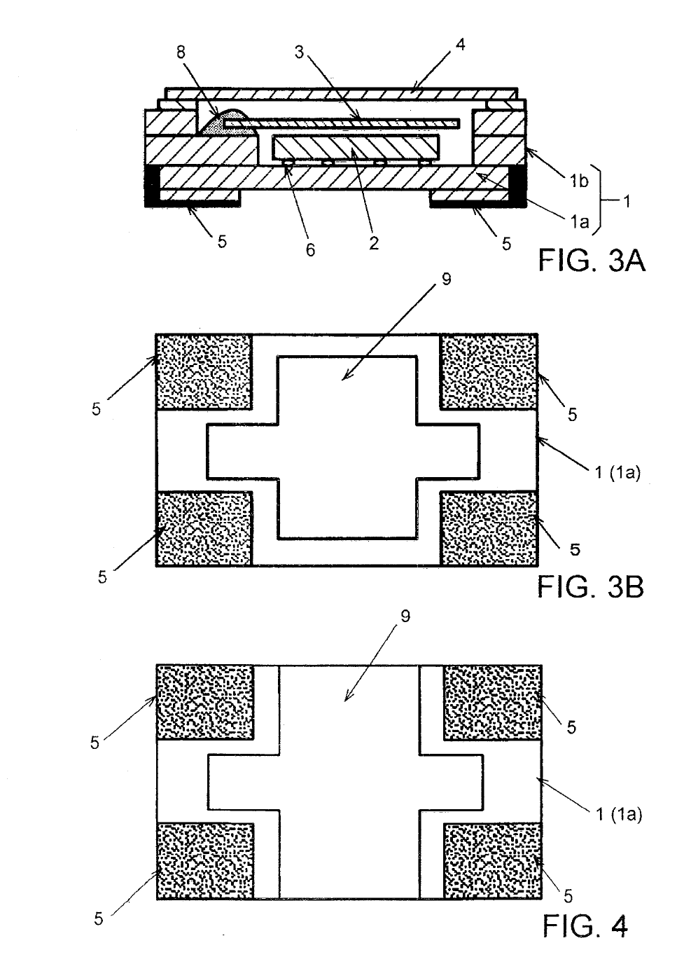

In FIGS. 3A and 3B which illustrate a surface mount crystal oscillator according to one embodiment of the present invention, the same components as those in FIGS. 1A and 1B are designated the same reference numerals, and repeated descriptions will be omitted.

The crystal oscillator illustrated in FIGS. 3A and 3B is similar to the one described above in that IC chip 2 and crystal blank 3 are contained in package body 1 formed of laminated ceramics, and metal cover 4 is placed over the recess to hermetically seal IC chip 2 and crystal blank 3 within the recess. The IC chip used in the conventional crystal oscillator is used as it is for IC chip 2, while the crystal blank described above with reference to FIG. 2 is used as it is for crystal blank 3. IC chip 2 is secured to the inner bottom surface of the recess in package body 1, while crystal blank 3 is secured to the top surface of a step formed on an inner wall of the recess in a manner similar to the foregoing. Mounting terminals 5 made of a metal film (i.e. electrode layer) are disposed at four corners on the outer bottom surface of package body 1. Write terminals are formed on an outer side surface of package body for writing temperature compensation data. In this embodiment, the surface mount crystal oscillator nominally has planar outside dimensions of 2.5 mm×2.0 mm and a height (thickness) of 0.8 mm.

Like the one described above, package body 1 comprises bottom wall layer 1a and frame wall layer 1b. Bottom wall layer 1a and frame wall layer 1b are similarly formed of a plurality of ceramic sheets which are laminated on each other. Package body 1 is formed by laminating a plurality of ceramic green sheets (i.e., unburned sheets of ceramic material) corresponding to such ceramic sheets having a predetermined shape, and subsequently burning the laminated ceramic green sheets. Then, in the crystal oscillator of this embodiment, in bottom wall layer 1a formed of laminated ceramic sheets, opening 9 is extended through a central region of the lowermost ceramic sheet, thereby forming a cavity or concaved portion in the outer bottom surface of package body 1.

Opening 9, i.e., cavity in the lowermost layer has a crucial shape bordered by mounting terminals 5 disposed at the four corners on the outer bottom surface of package body 1. In the illustrated example, the cavity does not extend to outer side surfaces of package body 1. In addition, no electrode layer or metal film is disposed on the bottom surface of the cavity, i.e., an exposed surface of bottom wall layer 1a through opening 9 extended through the lowermost layer. In the crystal oscillator of this embodiment, the lowermost layer of bottom wall layer 1a has a thickness of approximately 100 μm, including the thickness of mounting terminals 5. Since mounting terminals 5 themselves have a thickness of approximately 15 μm, the crucial cavity is formed to a depth of approximately 85 μm. From a viewpoint of the flatness of the outer bottom surface of package body 1, the thickness of mounting terminals 5 can be neglected.

In the configuration as described above, since the cavity is formed in the outer bottom surface of package body 1 without any electrode layer, an air layer having a small thermal conductivity is defined between the circuit board and crystal oscillator when the crystal oscillator is surface-mounted on the circuit board. Moreover, since the cavity is made in a crucial shape such that the cavity extends within the outer bottom surface of package body 1 except for the positions at which mounting terminals 5 are formed, the cavity can occupy an area at a larger proportion to the area of the outer bottom surface of package body 1 to increase the area of the air layer. Consequently, the crystal oscillator of this embodiment can alleviate the influence of a thermal change on the circuit board, as compared with package body 1 which has a flat outer bottom surface, the entirety of which is in contact with or in close proximity to a circuit board.

Also, no electrode layer, i.e., metal layer is disposed on the exposed surface in the cavity. Therefore, as compared with a cavity which is provided with electrodes such as write terminals, heat is not absorbed by or conducted to such electrodes, so that the crystal oscillator is even less affected by the influence of thermal changes on the circuit board.

In the crystal oscillator of the present invention as described above, since thermal conduction can be reduced between the circuit board and crystal oscillator when the crystal oscillator is mounted on the circuit board, even a thermal change, if any on the circuit board, would result in a smaller difference in temperature between IC chip 2 and crystal blank 3. Accordingly, the temperature sensor can detect a temperature which is substantially the same as the operating temperature of the crystal oscillator. Thus, the crystal oscillator exhibits a higher frequency stability to the temperature, and prevents a sudden change in oscillation frequency.

In the crystal oscillator illustrated in FIGS. 3A and 3B, the cavity (i.e., opening 9) formed in the outer bottom surface of package body 1 is closed in each side direction of the periphery of the outer bottom surface, but alternatively, the cavity may be opened, for example, on a pair of opposing sides on the outer bottom surface of the package body 1, as illustrated in FIG. 4, such that the cavity communicates with the outer side surfaces of package body 1. In this event, since the cavity are open to the outer side surfaces of package body 1, heat within cavity 9 can be radiated to the outside with greater ease. Such an advantage is expected by opening the cavity on at least one side of the outer bottom surface.

Generally, however, in steps of manufacturing the surface mount crystal oscillator, the formation of package body 1 involves laminating and burning ceramic green sheets having a size in which a plurality of crystal oscillators are integrated, and subsequently dividing them into individual package bodies. As such, from a viewpoint of manufacturing, the embodiment illustrated in FIGS. 3A and 3B is more advantageous because each package body 1 has an independent opening and therefore defines joints which can be set in the ceramic material sheets.

What is claimed is:

1. A surface mount crystal oscillator comprising:
a package body including a bottom wall layer, and a frame wall layer having an opening and laminated on said bottom wall layer, said opening defining a recess in said package body;
a crystal blank contained in said recess;
an IC chip contained in said recess, and having an oscillation circuit integrated therein, said oscillation circuit using said crystal blank; and
mounting terminals disposed at four corners on an outer bottom surface of said package body for use in mounting said crystal oscillator,
wherein said package body is formed with a cavity in at least a central region of the outer bottom surface, and no electrode layer is disposed in said cavity.

2. The crystal oscillator according to claim 1, wherein said cavity is open to at least one side of the outer bottom surface of said package body to communicate with an outer side surface of said package body.

3. The crystal oscillator according to claim 1, wherein each of said bottom wall layer and said frame wall layer is formed of laminated ceramic, said opening is formed through a lowermost ceramic sheet of the ceramic sheets which make up said bottom wall layer, and said cavity is formed by said opening in said lowermost ceramic sheet.

4. The crystal oscillator according to claim 1, wherein said IC chip is secured to an inner bottom surface of said recess, and said crystal blank is secured to a top surface of a step formed on an inner wall of said recess.

5. The crystal oscillator according to claim 1, wherein said IC chip includes a temperature compensation mechanism for compensating said crystal blank for temperature-frequency characteristics.

6. The crystal oscillator according to claim 1, further comprising a metal cover for closing an open end surface of said recess to hermetically seal said IC chip and said crystal blank within said recess.
